(19) United States
(12) Patent Application Publication
(10) Pub. No.: US 2014/0124739 A1
(43) Pub. Date: May 8, 2014

(54) SELF-ASSEMBLED QUANTUM COMPUTERS AND METHODS OF PRODUCING THE SAME

(71) Applicant: The University of Memphis Research Foundation, Memphis, TN (US)

(72) Inventor: Russell J. Deaton, Memphis, TN (US)

(73) Assignee: THE UNIVERSITY OF MEMPHIS RESEARCH FOUNDATION, Memphis, TN (US)

(21) Appl. No.: 14/076,084

(22) Filed: Nov. 8, 2013

Related U.S. Application Data
(60) Provisional application No. 61/724,258, filed on Nov. 8, 2012.

(51) Int. Cl. H01L 49/00

(52) U.S. Cl. CPC H01L 49/006
USPC 257/31; 438/1

(57) ABSTRACT

One aspect of the invention provides a self-assembled quantum computer including a plurality of quantum dots coupled by binding domains. Another aspect of the invention provides a method of self-assembling a quantum computer. The method includes: providing a plurality of quantum dots, each of the quantum dots coupled to between one and six binding domains; and facilitating coupling of the quantum dots through the binding domains, thereby self-assembling a quantum computer.

### CROSS-REFERENCE TO RELATED APPLICATION

This application claims priority to and the benefit of U.S. Patent Application No. 61/724,258 filed in the United States Patent and Trademark Office on Nov. 8, 2012, the entire contents of which are incorporated herein by reference.

### BACKGROUND

Measurement-based or one-way quantum computing uses a highly-entangled state of cubits to perform quantum computation. This state is called a graph state because the nodes of the graph are the qubits and entangling interactions between qubits are the edges. A graph must have certain characteristics in order to perform universal quantum computation. These characteristics include unbounded rank-width, which means that the connectivity of the graph is high enough to provide sufficient entanglement. Once assembled, computation is performed by single qubit measurements.

Despite extensive research in the field of quantum computing, commercially-available quantum computers remain both rare and expensive. Accordingly, there is a need for quantum computers that can be fabricated at relatively lower costs.

### SUMMARY OF THE INVENTION

One aspect of the invention provides a self-assembled quantum computer including a plurality of quantum dots coupled by binding domains.

This aspect of the invention can have a variety of embodiments. The binding domains can each have a binding temperature of 1. Each of the binding domains can be identical. The binding domains can be functional groups. The binding domains can be DNA sequences.

Each of the quantum dots can be coupled to between one and six binding domains.

The plurality of quantum dots can be coupled at about room temperature.

The self-assembled quantum computer can be a universal resource for measurement-based quantum computing.

Another aspect of the invention provides a method of self-assembling a quantum computer. The method includes: providing a plurality of quantum dots, each of the quantum dots coupled to between one and six binding domains; and facilitating coupling of the quantum dots through the binding domains, thereby self-assembling a quantum computer.

This aspect can have a variety of embodiments. The facilitating step can be performed at about room temperature.

The binding domains can each have a binding temperature of 1. Each of the binding domains can be identical. The binding domains can be functional groups. The binding domains can be DNA sequences.

The quantum computer can be a universal resource for measurement-based quantum computing.

### FIGURES

For a fuller understanding of the nature and desired objects of the present invention, reference is made to the following detailed description taken in conjunction with the figure wherein:

FIGS. 1 and 2 show temperature sets of tiles;

FIG. 3 depicts self-assembly of quantum dots through complimentary binding domains according to one embodiment of the invention;

FIG. 4 depicts self-assembly of quantum dots through complimentary binding domains according to one embodiment of the invention; and

FIG. 5 depicts a method of self-assembling a quantum computer according to an embodiment of the invention.

### DEFINITIONS

The instant invention is most clearly understood with reference to the following definitions:

As used in the specification and claims, the singular form “a,” “an,” and “the” include plural references unless the context clearly dictates otherwise.

“Room temperature” shall be understood to mean a temperature between about 15° C. and about 25° C. For example, “room temperature” includes, but is not limited to, temperatures between about 18° C. and about 23° C., temperature between about 19° C. and about 21° C. temperatures between about 24° C. and about 25° C., temperatures between about 20° C. and about 21° C., and the like.

Nucleic acid molecules useful in the methods of the invention may include any nucleic acid molecule that encodes a polypeptide of the invention (e.g., a DNA binding domain, a ligand binding domain, a protein-protein interaction domain), or a fragment thereof, to which a quantum dot may be coupled. Such nucleic acid molecules need not be 100% identical with an endogenous nucleic acid sequence, but will typically exhibit substantial identity. Polynucleotides having “substantial identity” to an endogenous sequence are typically capable of hybridizing with at least one strand of a double-stranded nucleic acid molecule. By “hybridize” is meant pair to form a double-stranded molecule between complementary polynucleotide sequences (e.g., a gene described herein), or portions thereof, under various conditions of stringency. (See, e.g., Wahl, G. M. and S. L. Berger (1987) Methods Enzymol. 152:399; Kimmel, A. R. (1987) Methods Enzymol, 152:507).

For example, stringent salt concentration will ordinarily be less than about 750 mM NaCl and 75 mM trisodium citrate, preferably less than about 500 mM NaCl and 50 mM trisodium citrate, and more preferably less than about 250 mM NaCl and 25 mM trisodium citrate. Low stringency hybridization can be obtained in the absence of organic solvent, e.g., formamide, while high stringency hybridization can be obtained in the presence of at least about 35% formamide, and more preferably at least about 50% formamide. Stringent temperature conditions will ordinarily include temperatures of at least about 30° C., more preferably of at least about 37° C., and most preferably of at least about 42° C. Varying additional parameters, such as hybridization time, the concentration of detergent, e.g., sodium dodecyl sulfate (SDS), and the inclusion or exclusion of carrier DNA, are well known to those skilled in the art. Various levels of stringency are accomplished by combining these various conditions as needed. In a preferred: embodiment, hybridization will occur at 30° C. in 750 mM NaCl, 75 mM trisodium citrate, and 1% SDS. In a more preferred embodiment, hybridization will occur at 37° C. in 500 mM NaCl, 50 mM trisodium citrate, 1% SDS, 35% formamide, and 100 μg/ml denatured salmon sperm DNA (ssDNA). In a most preferred embodiment, hybridization will occur at 42° C. in 250 mM NaCl, 25 mM trisodium citrate, 1% SDS, 50% formamide, and 200 μg/ml ssDNA. Useful variations on these conditions to modulate/alter self-assembly of quantum dot comprising molecules of the invention will be readily apparent to those skilled in the art.

“Hybridization” means hydrogen bonding, which may be Watson-Crick, Hoogsteen or reversed Hoogsteen hydrogen bonding, between complementary nucleobases. For example, adenine and thymine are complementary nucleobases that pair through the formation of hydrogen bonds. Nucleic acid hybridization techniques are well known to those skilled in the art and are described, for example, in Benton and Davis (Science 196:180, 1977); Grunstein and Hogness (Proc. Natl. Acad. Sci., USA 72:3961, 1975); Ausubel et al. (Current Protocols in Molecular Biology, Wiley Interscience, New York, 2001); Berger and Kimmel (Guide to Molecular Cloning Techniques, 1987, Academic Press, New York); and Sambrook et al., Molecular Cloning: A Laboratory Manual, Cold Spring Harbor Laboratory Press, New York.

Ranges provided herein are understood to be shorthand for all of the values within the range. For example, a range of 1 to 50 is understood to include any number, combination of numbers, or sub-range from the group consisting of 1, 2, 3, 4, 5, 6, 7, 8, 9, 10, 11, 12, 13, 14, 15, 16, 17, 18, 19, 20, 21, 22, 23, 24, 25, 26,27, 28, 29, 30, 31, 32, 33, 34, 35, 36, 37, 38, 39, 40, 41, 42, 43, 44, 45, 46, 47, 48, 49, or 50, as well as all intervening decimal values between the aforementioned integers such as, for example, 1.1, 1.2., 1.3, 1.4, 1.5, 1.6, 1.7, 1.8, and 1.9. With respect to sub-ranges, “nested sub-ranges” that extend from either end point of the range are specifically contemplated. For example, a nested sub-range of an exemplary range of 1 to 50 may comprise 1 to 10, 1 to 20, 1 to 30, and 1 to 40 in one direction, or 50 to 40, 50 to 30, 50 to 20, and 50 to 10 in the other direction.

By “specifically binds” is meant a compound or antibody that recognizes and binds a target of the invention (e.g., a polypeptide, a nucleic acid, a compound, etc.), but which does not substantially recognize and bind other molecules in a sample.

By “substantially identical” is meant a polypeptide or nucleic acid molecule exhibiting at least 50% identity to a reference amino acid sequence (for example, any one of the amino acid sequences described herein) or nucleic acid sequence (for example, any one of the nucleic acid sequences described herein). Preferably, such a sequence is at least 60%, more preferably 80% or 85%, and more preferably 90%, 95% or even 99% identical at the amino acid level or nucleic acid to the sequence used for comparison.

Sequence identity is typically measured using sequence analysis software (for example, Sequence Analysis Software Package of the Genetics Computer Group, University of Wisconsin Biotechnology Center, 1710 University Avenue, Madison, Wis. 53705, BLAST, BESTFIT, GAP, or PILEUP/PRETTYBOX programs). Such software matches identical or similar sequences by assigning degrees of homology to various substitutions, deletions, and/or other modifications. Conservative substitutions typically include substitutions within the following groups: glycine, alanine; valine, isoleucine, leucine; aspartic acid, glutamic acid, asparagine, glutamine; serine, threonine; lysine, arginine; and phenylalanine, tyrosine. In an exemplary approach to determining the degree of identity, a BLAST program may be used, with a probability score between e⁻³ and e⁻¹⁰⁰ indicating a closely related sequence.

### DESCRIPTION OF THE INVENTION

Embodiments of the invention provide self-assembled quantum computers and methods of self-assembling quantum computers.

### Quantum Computing

A quantum computer utilizes quantum mechanical phenomena, such as superposition and entanglement, to perform operations on data. Unlike traditional digital computers that store data in binary bits, quantum computers use quantum properties (represented as qubits) to represent data and perform operations on the data. A qubit can represent a one, a zero, or any quantum superposition of the one or zero states.

“One-way” or measurement-based quantum computing performs single qubit measurements on an entangled resource state (e.g., a graph state). Such a quantum computing technique is referred to as “one-way” because the resource state is destroyed by the measurements.

### Self-Assembly

In self-assembly, a small number of components automatically coalesce to form a target structure. Self-assembly is often discussed in terms of the Tile Assembly Model described in [8], in which components represented as tiles will bind when placed next to each other if the strength on the abutting sides exceeds at least a certain ambient “temperature.” In Temperature 2 self-assembly, two bonds are required for binding of adjacent tiles to occur. In Temperature 1 self-assembly, only a single bond required for binding of adjacent tiles to occur. For example, tiles interact through binding domains or “glues” and each tile has glue on each side of the tile. When glues match, the tiles interact and once the tiles are attached, they do not detach.

Although most research is focused on Temperature 2 self-assembly, Temperature 1 self-assembly has some advantages including that Temperature 1 bonds are relatively easier to achieve than Temperature 2 bonds.

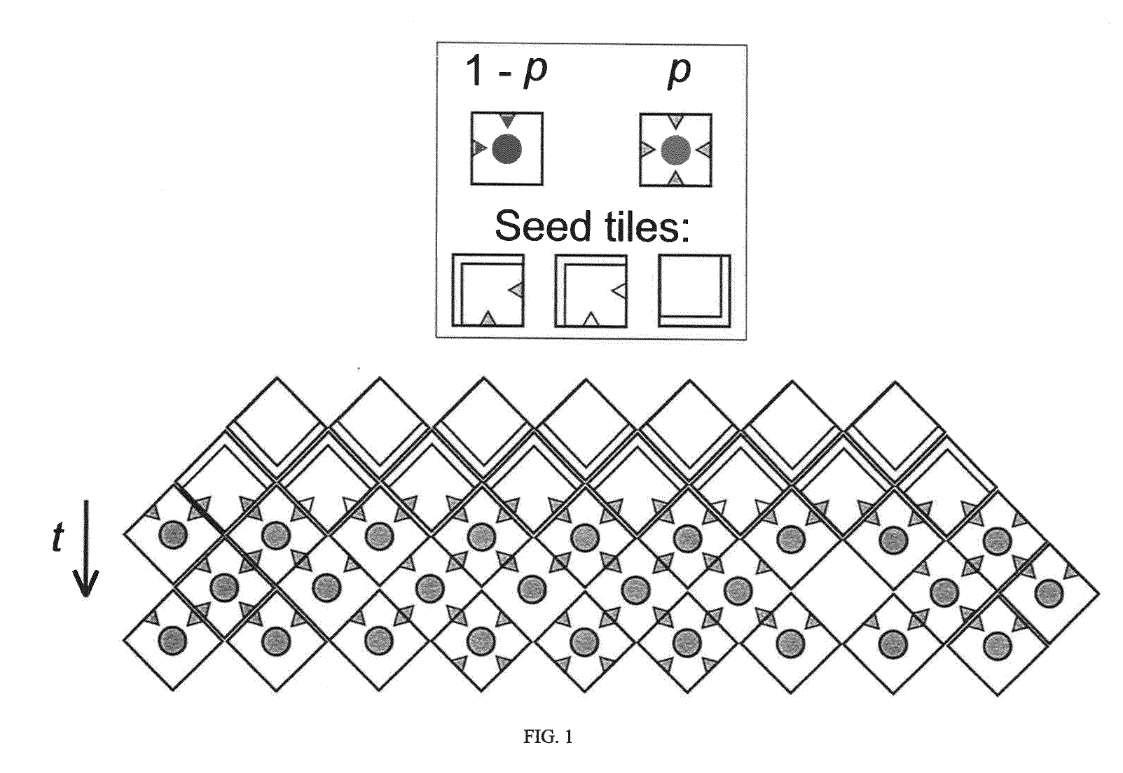

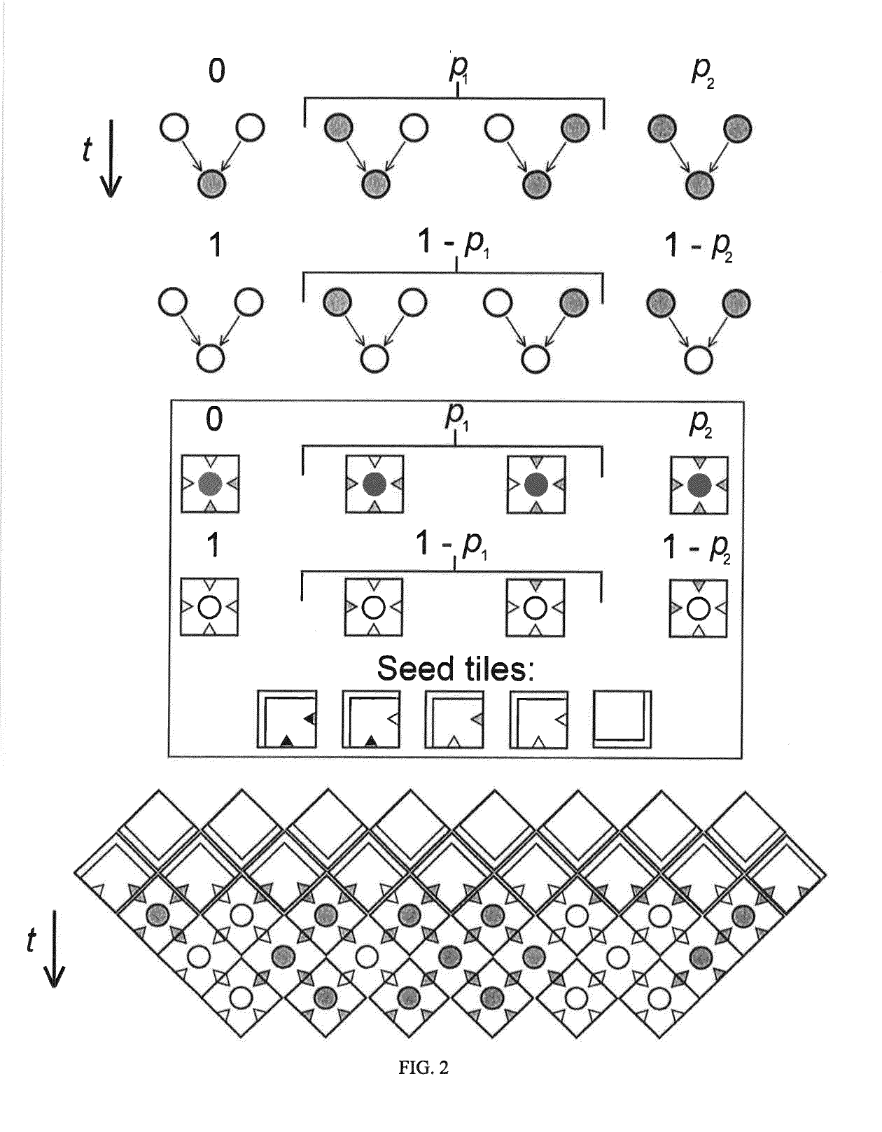

Further, to implement a model, such as a Domany-Kinzel cellular automation model, that exhibits directed percolation phase transitions tile concentration constraints are applied to the tile assembly model. The transitions follow particular conditions and determine active and inactive sites of a tile. In particular, aggregation behaviors may be programmed by varying the concentrations of the tiles which causes a tile to attach to more or less tiles based on concentration parameters. Each tile in a set of tiles may be assigned a specific concentration causing the attachment probability to correspond to specific parameters of the model. In other words, tile attachment is based on concentrations relative to other tile types. Thus, tile assembly systems are capable of being programmed to replicate the behavior of other physical systems in different fields and tile set designs may accomplish material properties through self-assembly. Specifically, temperature 1 (FIG. 1) and 2 (FIG. 2) sets of tiles are designed to assemble percolation clusters for graph states. The morphology and extent of the graphs are controlled by relative concentrations of tiles. The tiles in FIG. 2 can reproduce the entire phase diagram of directed percolation by controlling relative, concentration, including clusters that can be used for graph states. The tiles in FIG. 1 represent an implementation of the self-assembly of graph states that are particularly amenable to experimental implementation. Though they do not reproduce the entire phase diagram, they are capable of producing clusters for graph states and have the advantage of temperature 1 assembly. One binding domain is required. In both cases, the assembly is randomly seeded.

### Self-Assembled Quantum Computers

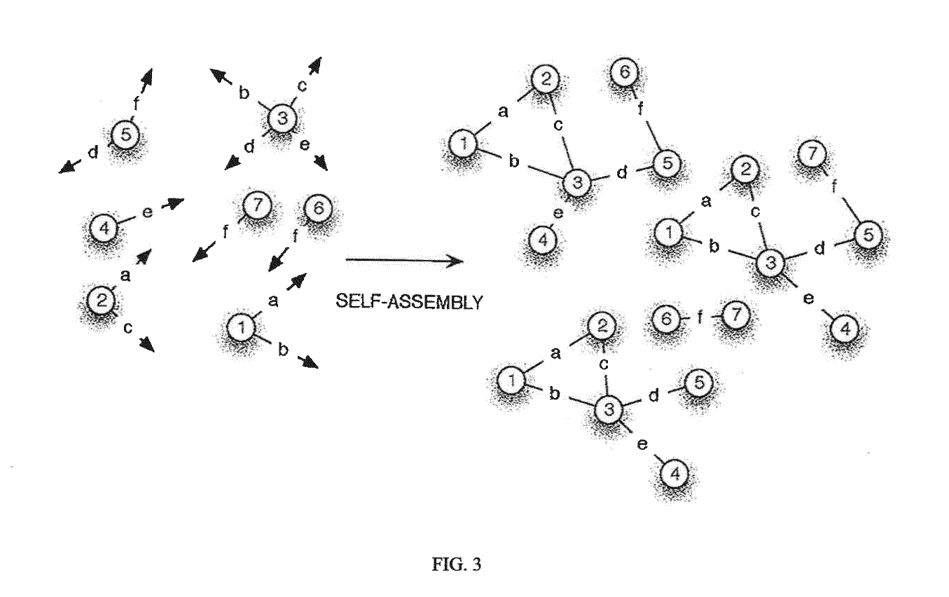

Referring now to FIG. 3, one aspect of the invention provides self-assembled quantum computers. The left portion of FIG. 3 depicts a plurality of quantum dots (represented as numbered circles) prior to self-assembly. Each of the quantum dots is coupled with one or more binding domains (labeled with letters).

The right half of FIG. 3 depicts a subset of the self-assembled graphs that can be generated from the quantum dots. Given the random nature of self-assembly, it is quite possible and/or probable that a plurality of different graphs will be assembled from a collection of individual quantum dots. Such diversity can be tolerated by conventional quantum computing techniques, which often express results in terms of probability instead of absolute binary terms.

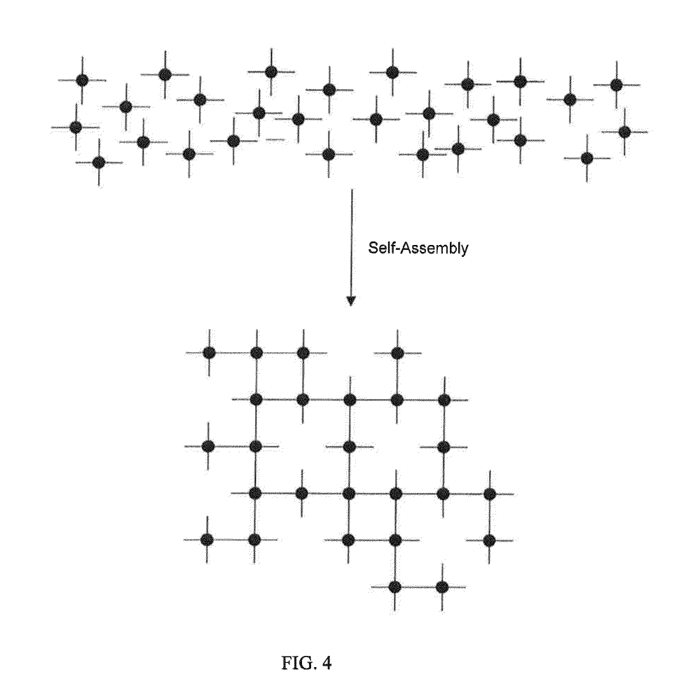

The resulting self-assembled graph can have a two-dimensional or a three-dimensional geometry. In one embodiment, the resulting graph is a two-dimensional lattice as depicted in FIG. 4.

### Quantum Dots

A quantum dot is a portion of matter whose excitons are confined in all three spatial dimensions. Quantum dots are generally fabricated from a semiconducting material such as indium arsenide, cadmium selenide, and the like. Quantum dots are commercially available from a variety of sources including under the QDOT® trademark from Life Technologies of Carlsbad, Calif.

### Binding Domains

A variety of binding domains/motifs may be chemically bonded/linked (e.g., covalently, non-covalently, etc.) to the quantum dots in order to facilitate entanglement of the quantum dots. For example, a binding domain(s) may include DNA or RNA polynucleotides, polypeptides, or fragments thereof, with specific or non-specific binding activity, antibodies, or fragments thereof, with specific binding activity, immunobinders, or fragments thereof, with specific binding activity, small molecules, etc. A binding domain can bind a target (e.g., a molecule, another binding domain, etc.) either specifically, or non-specifically.

Self-assembly of the bonded quantum dots into a structure or spatial configuration that facilitates quantum dot entanglement can result from the ability of the binding domain to specifically, or in some cases non-specifically, bind another molecule or molecules, thereby bringing the bound/linked quantum dots into a spatial position that promotes entanglement. For example, a DNA oligonucleotide can be used as a binding domain in which the quantum dot is bound/linked (e.g., covalently linked) to either the 3′ or 5′ end of the oligonucleotide. In this case, self-assembly can be driven by the hybridization of the DNA oligonucleotide with its Watson-Crick complement to assemble an entanglement-promoting structure. It is contemplated within the scope of the invention that the oligonucleotide can be identical, or substantially identical to, the target oligonucleotide molecule to which it binds. Advantageously, the use of oligonucleotides can allow formation of entanglement promoting structures with desired spatial characteristics (e.g., specific 2- or 3-dimensional structures). For example, multiple quantum dot labeled short oligonucleotides with different sequences can be targeted to a circular DNA molecule so as to cause the circular DNA to fold bid into a 3-dimensional structure based on the binding sites of the quantum dot labeled oligonucleotides.

Advantageously, self-assembly can be achieved at bonding temperature 1. That is, only a single bond (e.g., DNA-DNA, DNA-protein, protein-protein, group-group) is required to connect a pair of quantum dots.

In some embodiments, the binding domains can be identical. That is, a single set of complimentary binding domains (e.g. amine and carboxyl groups or a sequence of complementary DNA) can be used to couple the entire set of quantum dots. In other embodiments, a plurality of different binding domains are used.

Each quantum dot can be coupled with one or more binding domains. As discussed in Reference [5—C. Lee, et al., 70 Journal of Graph Theory 339 (2011)], additional binding domains can be added to a nanoparticle to predictably produce symmetrical arrangements of the binding domains. For example, between one and six binding domains can be coupled to the quantum nanodot to produce a variety of geometries.

Advantageously, self-assembly of quantum computers as described herein can occur at or about room temperature. Alternatively, self-assembly can occur at cold temperatures.

### Use of Self-Assembled Structure as Universal Resource

It is believed that the resulting self-assembled structure is almost guaranteed to produce a graph that is a universal resource for measurement-based quantum computing because the resulting self-assembly will exceed the percolation threshold shown to be sufficient to produce a universal resource in Reference [4—D. E. Browne, et al., 10 New Journal of Physics 023010 (2008)]. That is, that any quantum computation can be implemented in the resulting graph with only a polynomial overhead in spatial resources and time.

### Self-Assembly Methods

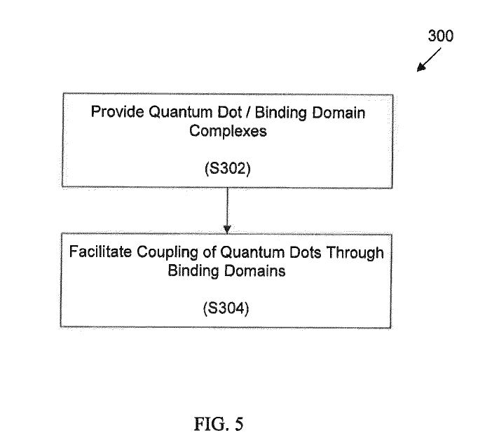

Referring now to FIG. 5, a method 300 of self-assembling a quantum computer is provided.

In step S302, a plurality of quantum dots are provided as described herein. The quantum dots can have between one and six binding domains bonded to the quantum dots.

In step S304, the coupling of the quantum dots through the binding domains is facilitated. Coupling can be achieved through various techniques known in the art including stirring, agitations, modulation of temperature, and the like.

### REFERENCES

[1] R. Raussendorf & H. J. Briegel, 86 Phys. Rev, Lett. 5188 (2001).

[2] M. Van Den Nest, et al., 97 Phys. Rev. Lett. 150504 (2006).

[3] M. Van Den Nest, et al., 9 New Journal of Physics, 204 (2007).

[4] D. E. Browne, et al., 10 New Journal of Physics 023010 (2008).

[5] C. Lee, et al., 70 Journal of Graph Theory 339 (2011).

[6] J.-H. Kim & J.-W. Kim, 26 Langmuir 18634 (2010).

[7] J.-W. Kim, et al., 50 Angew. Chem. Int. Ed. 2011, 9185 (2011)

[8] E. Winfree, “Algorithmic self-assembly of DNA,” Ph. D. thesis, California Institute of Technology (1998).

### Equivalents

While certain embodiments according to the invention have been described, the invention is not limited to just the described embodiments. Various changes and/or modifications can be made to any of the described embodiments without departing from the spirit or scope of the invention. Also, various combinations of elements, steps, features, and/or aspects of the described embodiments are possible and contemplated even if such combinations are not expressly identified herein.

### INCORPORATION BY REFERENCE

The entire contents of all patents, published patent applications, and other references cited herein are hereby expressly incorporated herein in their entireties by reference.

1. A self-assembled quantum computer comprising:
a plurality of quantum dots coupled by binding domains;

2. The self-assembled quantum computer of claim 1, wherein the binding domains each have a binding temperature of 1.

3. The self-assembled quantum in computer of claim 1, wherein each of the binding domains is identical.

4. The self-assembled quantum computer of claim 1, wherein the binding domains are functional groups.

5. The self-assembled quantum computer of claim 1, wherein the binding domains are DNA sequences.

6. The self-assembled quantum computer of claim 1, wherein each of the quantum dots is coupled to between one and six binding domains.

7. The self-assembled quantum computer of claim 1, wherein the plurality of quantum s are coupled at about room temperature.

8. The self-assembled quantum computer of claim 1, wherein the self-assembled quantum computer is a universal resource for measurement-based quantum computing.

9. A method of self-assembling a quantum computer, the method comprising:
providing a plurality of quantum dots, each of the quantum dots coupled to between one and six binding domains; and
facilitating coupling of the quantum dots through the binding domains;
thereby self-assembling a quantum computer.

10. The method of claim 9, wherein the facilitating step is performed at about room temperature.

11. The method of claim 9, wherein the binding domains each have a binding temperature of 1.

12. The method of claim 9, wherein each of the binding domains is identical.

13. The method of claim 9, wherein the binding domains are functional groups.

14. The method of claim 9, wherein the binding domains are DNA sequences.

15. The method of claim 9, wherein the quantum computer is a universal resource for measurement-based quantum computing.
